(19) United States
(12) Patent Application Publication
(10) Pub. No.: US 2025/0114871 A1
(43) Pub. Date: Apr. 10, 2025

(54) LASER CUTTING DEVICE AND LASER CUTTING METHOD USING THE SAME

(71) Applicant: Samsung Display Co., LTD., Yongin-si (KR)

(72) Inventors: Je Yun RYU, Yongin-si (KR); Inho LEE, Yongin-si (KR)

(21) Appl. No.: 18/742,137

(22) Filed: Jun. 13, 2024

(30) Foreign Application Priority Data
Oct. 6, 2023 (KR) 10-2023-0133652

(51) Int. Cl. B23K 26/38; B23K 26/064; B23K 26/082; B23K 26/402; B23K 103/00; H10K 71/00

(52) U.S. Cl. CPC B23K 26/38; B23K 26/064; B23K 26/082; B23K 26/402; H10K 71/851; B23K 2103/54

(57) ABSTRACT

A laser cutting device includes: a light source part configured to emit a laser beam; a stage on which a workpiece is placed; an optical system including a scanning unit configured to irradiate the laser beam to the stage and change an irradiation direction of the laser beam along a shape set for the workpiece, and optical devices disposed on a path of the laser beam, which is from the light source part to the scanning unit; and an optical path selection part disposed between the light source part and the optical system and configured to adjust the path of the laser beam so that the laser beam moves to one of the optical devices.

This application claims priority to Korean Patent Application No. 10-2023-0133652, filed on Oct. 6, 2023, and all the benefits accruing therefrom under 35 U.S.C. § 119, the content of which in its entirety is herein incorporated by reference.

### BACKGROUND

### (a) Technical Field

This disclosure relates to a laser cutting device and a laser cutting method using the same.

### (b) Description of the Related Art

A laser cutting device can be used to cut a display device that uses, for example, a glass-based substrate as a base substrate to a desired standard.

Examples of the display device may include an organic light emitting display (“OLED”) or a liquid crystal display (“LCD”).

And, when manufacturing such a display device, a laser beam is irradiated to the substrate of the product using the laser cutting device to cut it into the desired size and shape. As this laser beam moves along the shape of the substrate, there is bound to be a part where the shape changes to a curve, and in this part, the moving speed of the laser beam changes, that is, an acceleration/deceleration section may occur.

### SUMMARY

The present disclosure is to provide a laser cutting device that can switch a workpiece from straight machining to curved machining without reducing the driving speed of the scanning unit.

A laser cutting device according to an embodiment of the present invention includes: a light source part configured to emit a laser beam; a stage where a workpiece is placed; an optical system including a scanning unit configured to irradiate the laser beam to the stage and change an irradiation direction of the laser beam along a shape set for the workpiece, and optical devices disposed on a path of the laser beam, which is from the light source part to the scanning unit; and an optical path selection part disposed between the light source part and the optical system and configured to adjust the path of the laser beam so that the laser beam moves to one of the optical devices.

The optical devices may include a first optical device and a second optical device each having a diffraction part configured to convert an incident laser beam into polarized light, and the diffraction part may have a diffraction pattern in which a vibration direction of the polarized light is selected.

The diffraction pattern of the diffraction part of the first optical device and the diffraction pattern of the diffraction part of the second optical device may be different from each other in a stationary state.

The diffraction pattern of the diffraction part of the second optical device in the stationary state may be tilted, compared to the diffraction pattern of the diffraction part of the first optical device, in a direction opposite to the rotation direction in which the diffraction part of the second optical device rotates.

A rotation time of the diffraction part of the first optical device and a rotation time of the diffraction part of the second optical device may not at least partially overlap.

The set shape of the workpiece may have a straight machining portion and a curved machining portion, and the optical path selection part may adjust the path of the laser beam to be directed to the first optical device during cutting the straight machining portion, and adjust the path of the laser beam to be directed to the second optical device during cutting the curved machining portion.

The diffraction part of the first optical device may be in a stationary state when the laser beam is incident on the first optical device, and the diffraction part of the second optical device may be in a rotating state when the laser beam is incident on the second optical device.

The scanning unit may change the path of the laser beam at a constant speed.

The optical devices may further include a third optical device having a diffraction part configured to convert an incident laser beam into polarized light, the diffraction part may have a diffraction pattern in which a vibration direction of the polarized light is selected. The diffraction pattern of the diffraction part of the first optical device, the diffraction pattern of the diffraction part of the second optical device, and the diffraction pattern of the diffraction part of the third optical device may be different from each other in a stationary state.

The set shape of the workpiece may have a straight machining portion and a curved machining portion, and the optical path selection part may adjust the path of the laser beam to be directed to the first optical device or the third optical device during cutting the straight machining portion, and may adjust the path of the laser beam to be directed to the second optical device during cutting the curved machining portion.

The laser cutting method according to an embodiment of the present invention includes: preparing a workpiece on a stage; emitting a laser beam from a light source and selectively enters the laser beam into a first optical device or a second optical device. The method further includes: cutting the workpiece by a scanning unit to move an irradiation direction of the laser beam, to the stage, outputted from the first optical device or the second optical device along a shape set for the workpiece.

The selectively entering of the laser beam on the first optical device or the second optical device may include adjusting a path of the laser beam, which is from the light source part to the scanning unit, by an optical path selection part.

The shape set for the workpiece may include a straight machining portion and a curved machining portion. The straight machining portion is cut by the laser beam, which passes through the first optical device, and the curved machining portion is cut by the laser beam, which passes through the second optical device.

The adjusting of the path of the laser beam by the optical path selection part may include adjusting the path of the laser beam to be directed to the first optical device when a diffraction part of the first optical device is in a stationary state, and adjusting the path of the laser beam to be directed to the second optical device when a diffraction part of the second optical device is in a rotating state.

A vibration direction of the laser beam passing through the first optical device may be parallel to the straight machining portion of the workpiece.

The vibration direction of the laser beam passing through the second optical device may rotate, and the vibration direction of the laser beam passing through the second optical device may correspond to a tangent of the curved machining portion of the workpiece.

The diffraction part of the second optical device may start rotating when the laser beam enters into the first optical device.

Time required to adjust the path of the laser beam by the optical path selection part may be equal to or shorter than time required for the scanning unit to change the irradiation direction of the laser beam.

The diffraction part of the first optical device may start rotating when the laser beam enters into the second optical device.

The straight machining portion may include a first straight machining portion and a second straight machining portion. The first straight machining portion may be cut by the laser beam passing through the first optical device, and the second straight machining portion may be cut by the laser beam passing through a third optical device. An extension line of the first straight machining portion and an extension line of the second straight machining portion may intersect each other.

According to the embodiments of the present invention, when the cutting path is switched between the curved machining portion and the straight processing portion on the workpiece, the process can be performed while maintaining a constant speed of the scanning unit placed in the laser cutting device without decelerating, thus effectively reducing the cutting process time.

### BRIEF DESCRIPTION OF THE DRAWINGS

FIG. 1 is a diagram illustrating a laser cutting device according to one embodiment.

FIG. 2 is a diagram illustrating cutting a curved machining portion of a workpiece in the laser cutting device of FIG. 1.

FIG. 3 is a diagram illustrating cutting a second straight machining portion of a workpiece in the laser cutting device of FIG. 1.

FIG. 4 is a diagram showing a diffraction part in the laser cutting device of FIG. 1.

FIG. 5 is a flow chart showing a laser cutting method according to one embodiment.

FIG. 6 is a graph showing the direction of the diffraction pattern of the diffraction part according to process time.

FIG. 7 is a graph comparing laser cutting using a single optical device and laser cutting using a plurality of optical devices according to this embodiment.

FIG. 8 is a diagram showing a laser cutting device according to another embodiment.

FIG. 9 is a graph showing changes in the diffraction part over time of a laser cutting device according to another embodiment.

### DETAILED DESCRIPTION

Hereinafter, with reference to the attached drawings, various embodiments of the present invention will be described in detail so that those skilled in the art can easily implement the present invention.

The invention may be implemented in many different forms and is not limited to the embodiments described herein.

In order to clearly explain the present invention, parts that are not relevant to the description are omitted, and identical or similar components are assigned the same reference numerals throughout the specification.

component shown in the drawings are arbitrarily shown for convenience of explanation, the present invention is not necessarily limited to that which is shown.

In the drawing, the thickness is enlarged to clearly express various layers and areas.

And in the drawings, for convenience of explanation, the thicknesses of some layers and regions are exaggerated.

When a part of a layer, membrane, region, or plate is said to be “above” or “on” another part, this includes not only cases where it is “directly above” the other part, but also cases where there is another part in between.

Conversely, when a part is said to be “right on top” of another part, it means that there is no other part in between.

In addition, being “above” or “on” a reference part means being located above or below the reference part, and does not necessarily mean being located “above” or “on” the direction opposite to gravity.

Throughout the specification, when it is said that a part “includes” a certain element, this means that it may further include other elements rather than excluding other elements, unless specifically stated to the contrary.

Throughout the specification, when we say “on a plane,” this means when the target part is viewed from above, and when we say “on a cross section,” it means when we look at a cross section cut vertically from the target part from the side.

Throughout the specification, when “connected” is used, this does not mean only when two or more components are directly connected, but also when two or more components are indirectly connected through other components or when they are physically connected, in addition, in the case of being electrically connected, it may include each part being referred to by different names depending on location or function, but being substantially integrated.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

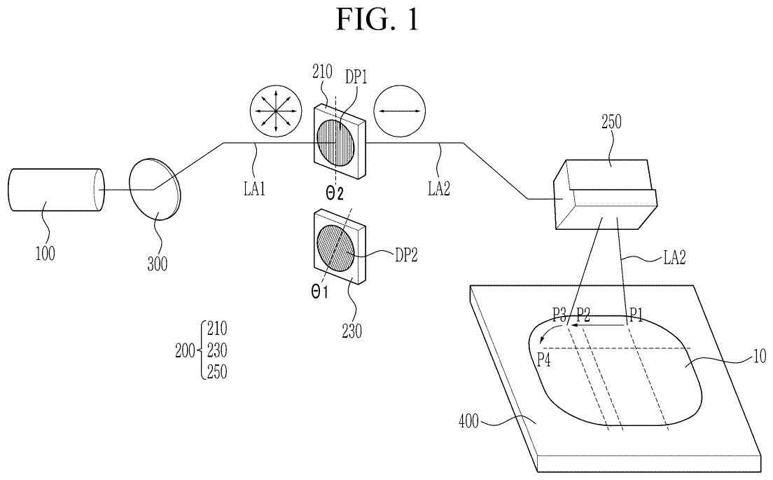

Hereinafter, a laser cutting device according to an embodiment will be described with reference to FIGS. 1 to 4.

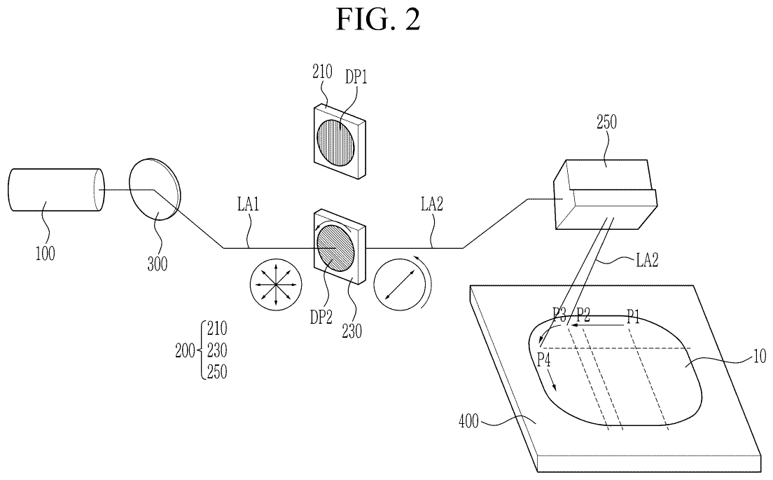

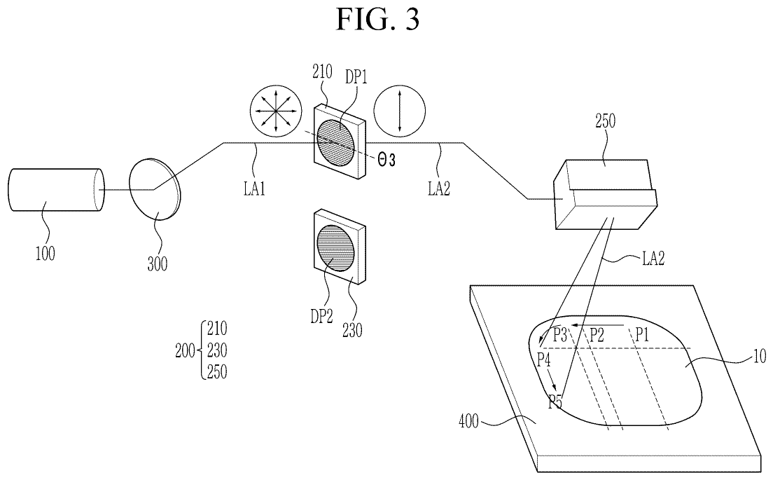

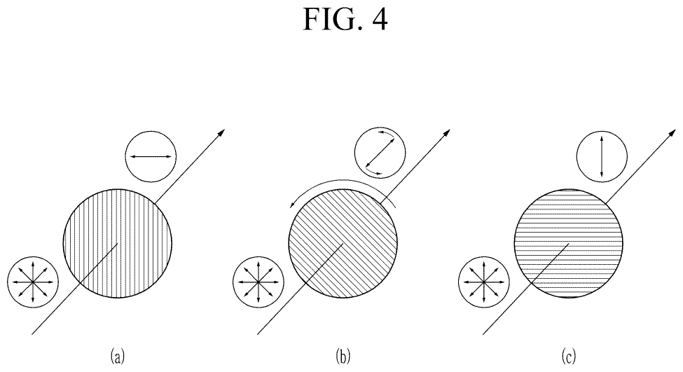

FIG. 1 is a view showing a laser cutting device according to an embodiment, FIG. 2 is a view showing cutting a curved machining portion of a workpiece in the laser cutting device of FIG. 1, and FIG. 3 is a view showing the laser cutting device of FIG. 1. This is a diagram showing cutting the second straight machining portion of the workpiece in the device, and FIG. 4 is a diagram showing a diffraction part in the laser cutting device of FIG. 1.

First, when explaining θ1, θ2, and θ3 shown in FIGS. 1 to 3, θ1, θ2, and θ3 mean angles for expressing the relative directionality of the diffraction pattern of each diffraction part, and it should not be understood as expressing angles as numbers.

Referring to FIGS. 1 to 4, a laser cutting device according to an embodiment includes a light source part 100, an optical system 200, an optical path selection part 300, and a stage 400.

The light source part 100 may generate and emit input light LA1.

The input light LA1 is a laser beam and may include gas lasers such as carbon dioxide lasers, excimer lasers, helium-neon lasers, etc., or solid lasers such as ruby lasers, glass lasers, YAG lasers, YLF lasers, etc., but is not limited to this.

The input light LA1 may be a Gaussian laser beam in which the intensity of the beam is concentrated in the center and the vibration direction is not specified.

That is, the input light LA1 may be a laser beam, which vibrates in all directions perpendicular to a propagation direction of the laser beam. In other words, the input light LA1 is a non-polarized light.

The optical system 200 may be located in the path of the laser beam.

Input light LA1 passing through the optical system 200 may be converted into output light LA2.

The output light LA2 may be polarized light whose vibration direction can be specified.

The optical system 200 is disposed between the light source part 100 and the stage 400 on the optical path, and can irradiate the output light LA2 in a direction toward the stage 400.

The optical system 200 may include optical devices and a scanning unit 250.

The optical devices may include a first optical device 210 and a second optical device 230.

The first optical device 210 may convert input light LA1 into output light LA2.

The first optical device 210 may be a diffraction optical device (“DOE”).

The first optical device 210 may include a diffraction part DP1 that converts the input light LA1 into the output light LA2.

That is, input light LA1 whose vibration direction is not specified may be converted into output light LA2 having a specific vibration direction while passing through the diffraction part DP1 of the first optical device 210.

The diffraction part DP1 of the first optical device 210 may have a diffraction pattern in a specific direction, and the vibration direction of the output light LA2 may vary depending on the diffraction pattern of the diffraction part DP1.

The diffraction part DP1 of the first optical device 210 may be in a stationary state while the laser beam is incident.

Accordingly, the input light LA1 enters into the first optical device 210 and is converted to polarized light by the diffraction part DP1, and then the polarized output light LA2 is emitted from (i.e., passing through) the first optical device 210. Hence, the vibration direction of the output light LA2 can be maintained constant.

The vibration direction of the output light LA2 emitted from the first optical device 210 may be parallel to the cutting direction of the straight machining portion (point P1 to point P3) of the workpiece 10.

That is, when cutting the workpiece 10 in a straight line from point P1 to point P3, the vibration direction of the output light LA2 emitted from the first optical device 210 may be parallel to the straight line connecting points P1 to P3.

When the laser beam LA1 that was incident on the first optical device 210 begins to incident on the second optical device 230, the diffraction part DP1 of the first optical device 210, which was in a stationary state, may rotate.

As the diffraction part DP1 rotates, the diffraction pattern of the diffraction part DP1 also rotates, and the direction of the diffraction pattern may change.

As an example, referring to FIGS. 2 and 4, the diffraction part DP1 of the first optical device 210 may keep a diffraction pattern as shown in (a) of FIG. 4 while the laser beam passes through the first optical device 210, and after the laser beam (i.e., the input light LA1) passes through the first optical device 210, during the resting period until the laser beam LA1 is incident again, the first optical device 210 can be rotated 90° to become the state shown in (c) of FIG. 4.

In FIGS. 1 to 4, the diffraction part DP1 of the first optical device 210 is shown to rotate by 90° while the laser beam LA1 is incident on the second optical device 230, however, the invention is not limited to this, and in the second optical device 230, the angle at which the diffraction part DP1 of the first optical device 210 rotates may be set in various ways depending on the cutting shape of the workpiece 10.

The second optical device 230 may convert the input light LA1 into the output light LA2.

The second optical device 230 may be a diffractive optical device.

The second optical device 230 may include a diffraction part DP2, which converts the input light LA1 into the output light LA2.

That is, input light LA1 whose vibration direction is not specified may be converted into output light LA2 having a specific vibration direction (i.e., polarized light) while passing through the diffraction part DP2 of the second optical device 230.

The diffraction part DP2 of the second optical device 230 may have a diffraction pattern in a specific direction, and the vibration direction of the output light LA2 may vary depending on the diffraction pattern of the diffraction part DP2.

The diffraction part DP2 of the second optical device 230 may have the same shape as the diffraction part DP1 of the first optical device 210, and the direction of the diffraction pattern of the diffraction part DP2 may be different from the direction of the diffraction pattern of the part DP1.

As an example, referring to FIG. 1, the diffraction part DP2 of the second optical device 230 in the initial state before the cutting process starts may be tilted by the angle θ2-θ1 compared to (i.e., with respect to) the diffraction part DP1 of the first optical device 210.

In an embodiment, the diffraction part DP2 of the second optical device 230 may rotate while the laser beam enters into the second optical device 230.

As the diffraction part DP2 rotates, the diffraction pattern of the diffraction part DP2 also rotates, and the direction of the diffraction pattern may change.

Accordingly, the vibration direction of the laser beam (i.e., the input light LA1) converted into polarized light (i.e., the output light LA2) by the diffraction part DP2 of the second optical device 230 may rotate along the processing direction of the curved machining portion of the workpiece 10.

That is, when cutting the curved machining portion (point P3 to point P4) of the workpiece 10, the output light LA2 emitted from the second optical device 230 corresponds to the cut curve of the workpiece 10, so the vibration direction (i.e., polarized direction) can be rotated.

The tangent of the curved machining portion (point P3 to point P4) of the workpiece 10 to be cut continues to change along the curved cutting path, and of the output light LA2 emitted from (i.e., passing through) the diffraction part DP2 of the second optical device 230, the vibration direction may correspond to the tangent of the curved path.

For example, if the direction of the diffraction part DP2 of the second optical device 230 rotates counterclockwise, the vibration direction (i.e., polarized direction) of the output light LA2 may also rotate counterclockwise.

In the initial state before the cutting process begins, the diffraction part DP2 of the second optical device 230 may be tilted in the opposite direction of rotation compared to the diffraction part DP1 of the first optical device 210.

As an example, referring to FIGS. 1 and 4, in the initial state, as the diffraction part DP2 of the second optical device 230 is tilted clockwise by the angle θ2-θ1 compared to the diffraction part DP1 of the first optical device 210.

However, this is an example of a case where the diffraction part DP2 of the second optical device 230 rotates counterclockwise during the cutting process, and is not limited thereto.

When the diffraction part DP2 of the second optical device 230 rotates clockwise during the cutting process, the diffraction part DP2 of the second optical device 230 in the initial state may be tilted counterclockwise by the angle θ2-θ1 relative to the diffraction part DP1 of the first optical device 210.

The scanning unit 250 may irradiate the output light LA2 emitted from the first optical device 210 or the second optical device 230 and incident on the scanning unit 250 to the stage 400.

The shape to be cut for the workpiece 10 may be set in advance, and the scanning unit 250 may irradiate the laser beam while moving the propagation direction of the laser beam along the shape set for the workpiece 10.

That is, the laser beam irradiated by the scanning unit 250 moves along the preset shape of the workpiece 10 and can cut the workpiece 10.

The scanning unit 250 may be interworked to the first optical device 210 to irradiate output light LA2 having a certain vibration direction along the straight machining portion (point P1 to point P3) of the workpiece 10.

Additionally, the scanning unit 250 may be interworked to the second optical device 230 to irradiate the output light LA2 whose vibration direction rotates along the curved machining portion (point P3 to point P4) of the workpiece 10.

Although not shown, the scanning unit 250 may include an optical path change member such as a galvanometer.

The optical path selection part 300 may be disposed on the optical path between the light source part and the optical system 200.

The optical path selection part 300 changes the optical path so that the input light LA1 emitted from the light source part 100 and incident on the optical path selection part 300 is directed to the first optical device 210 or the second optical device 230.

The optical path selection part 300 may include a galvanometer-mirror or an acousto-optic deflector (“AOD”).

The stage 400 may support the workpiece 10.

The stage 400 may provide a flat surface on which the workpiece 10 can be seated.

Although not shown, a separate component capable of moving the stage 400 may be placed below or on the side of the stage 400.

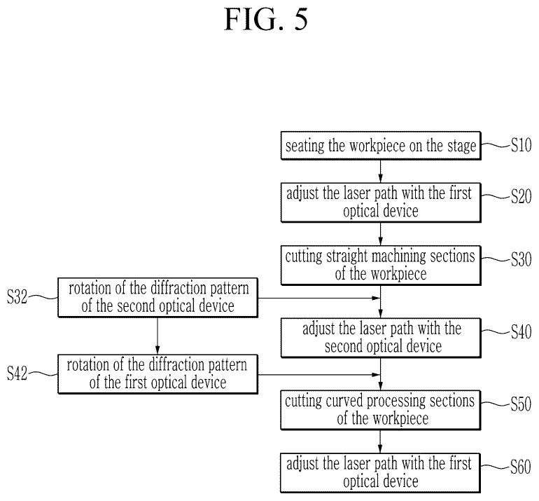

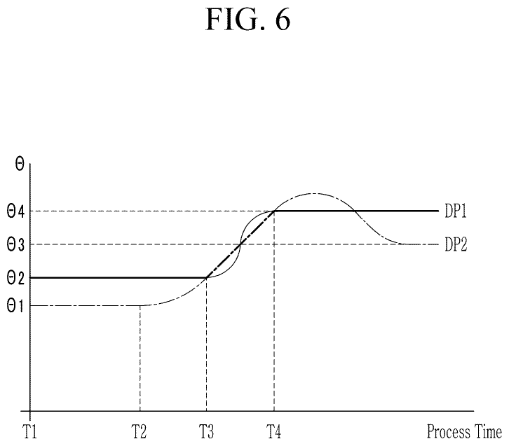

Hereinafter, a method of laser cutting using a laser cutting device according to an embodiment will be described with reference to FIGS. 5 and 6 along with FIGS. 1 to 4.

FIG. 5 is a flowchart showing a laser cutting method according to one embodiment.

Referring to FIG. 5, first, the workpiece 10 is prepared on the stage 400 (S10).

Specifically, the workpiece 10 to be laser cut is placed on the upper surface of the stage 400.

Next, a laser beam is generated and emitted from the light source part 100.

The light source part may emit a Gaussian-shaped laser beam whose vibration direction is not specified.

The laser beam incident on the optical path selection part 300 may proceed to the first optical device 210.

At this time, the optical path selection part 300 may adjust the direction of travel of the incident laser beam so that the laser beam travels toward the first optical device 210 (S20).

In this embodiment, the case of machining the straight cutting portion of the workpiece 10 first is exemplified, but the invention is not limited to this, and in the case of machining the curved cutting portion of the workpiece 10 first, the optical path selection part 300 can change the path of the incident laser beam so that it first heads to the second optical device 230.

The laser beam traveling to the first optical device 210 may change its shape after passing through the diffraction part DP1 of the first optical device 210.

That is, when the incident light LA1 whose vibration direction is not specified in a Gaussian form passes through the diffraction part DP1 of the first optical device 210, it can become the emitted light LA2 having a vibration direction, and at this time, the vibration direction of the emitted light LA2 may be parallel to the straight machining portion (point P1 to point P3) of the workpiece 10.

The laser beam emitted from (i.e., passing through) the first optical device 210 is incident on the scanning unit 250, and the scanning unit 250 may irradiate the incident laser beam along a preset path.

The laser beam emitted from the first optical device 210 is irradiated by the scanning unit 250 to the straight machining portion (point P1 to point P3) on the workpiece 10 to cut the workpiece 10 in a straight line (S30).

Since the vibration direction of the laser beam emitted from the first optical device 210 is parallel to the cutting path of the straight machining portion (point P1 to point P3), the straight machining portion of the workpiece 10 can be cut smoothly without any winding portion.

While the laser beam is incident on the first optical device 210, the diffraction part DP2 of the second optical device 230 may start rotating (S32).

That is, while the cutting process for the straight machining portion (point P1 to point P3) of the workpiece 10 is in progress, when the laser beam is irradiated to the point P2 on the workpiece 10, the diffraction part DP2 of the second optical device 230 may begin rotating.

Accordingly, the diffraction pattern of the diffraction part DP2 of the second optical device 230 may also rotate.

Next, the optical path selection part 300 may change the path of the incident laser beam in order to cut the curved machining portion (point P3 to point P4) of the workpiece 10.

The path of the laser beam that has passed through the optical path selection part 300 may be changed to head toward the second optical device 230.

For example, the optical path selection part 300 may be a device that adjusts the optical path by rotating the mirror, such as a galvano mirror.

The optical path selection part 300 performs operations such as rotating to change the path of the laser beam. At this time, the operation of the optical path selection part 300 causes the scanning unit 250 to move the travel path of the laser beam. The speed for the optical path selection part 300 to move the travel path of the laser beam be the same to or faster than the speed for the scanning unit 250 to move the travel path of the laser beam.

Therefore, when the propagation direction of the laser beam changes from the straight machining portion (point P1 to point P3) of the workpiece 10 to the curved machining portion (point P3 to point P4), the optical path selection part 300 selects the travel path of the laser beam. Even when changing the travel path of the laser beam from the first optical device 210 to the second optical device 230, interruption of the process can be prevented.

The laser beam proceeded to the second optical device 230 may be changed into polarized light after passing through the diffraction part DP2 of the second optical device 230.

That is, when the incident light LA1 whose vibration direction is not specified passes through the diffraction part DP2 of the second optical device 230, it may become the emitted light LA2 having a specific vibration direction (i.e., polarized direction).

The diffraction part DP2 of the second optical device 230 can rotate.

In FIGS. 2 and 4, the diffraction part DP2 of the second optical device 230 is shown to rotate counterclockwise, but the present invention is not limited thereto.

A laser beam may enter the diffraction part DP2 while the diffraction part DP2 rotates.

At this time, the vibration direction of the laser beam incident on the diffraction part DP2 is specified, and as the diffraction part DP2 rotates, the vibration direction may also rotate.

That is, when the diffraction part DP2 rotates counterclockwise, the vibration direction of the laser beam may also rotate counterclockwise.

Each vibration direction of the rotating laser beam may correspond to each tangent of the curved machining portion (point P3 to point P4) of the workpiece 10.

FIG. 6 is a graph showing the direction of the diffraction pattern of the diffraction part according to process time.

θ1, θ2, θ3, and θ4 shown in FIG. 6 indicate the degree to which the diffraction pattern of the diffraction part is relatively rotated, and do not mean an absolute angle.

That is, θ1, θ2, θ3, and θ4 should be understood to mean relative rotation angles.

For example, θ1 may mean rotated clockwise with respect to θ2, and θ3 and θ4 may mean rotated counterclockwise with respect to θ2.

Additionally, in FIGS. 6, T1, T2, T3, and T4 may refer to the times at which the laser beam is irradiated to points P1, P2, P3, and P4 on the workpiece, respectively.

Referring to FIG. 6, the diffraction part DP2 of the second optical device 230 may remain stationary and not rotate in its initial state before the laser beam (i.e., the input light LA1) is emitted from the light source part 100.

Afterwards, the diffraction part DP2 of the second optical device 230 rotates, and the laser beam may enter the diffraction part DP2 later than when the diffraction part DP2 starts rotating.

In the initial state before the laser beam (i.e., the input light LA1) is emitted from the light source part 100, the diffraction part DP2 of the second optical device 230 may be tilted in the direction opposite to the rotation direction compared to the diffraction part DP1 of the first optical device 210.

Referring to FIGS. 1 and 6, in the initial state, the diffraction part DP2 of the second optical device 230 may be tilted clockwise by the angle θ2-θ1 compared to the diffraction part DP1 of the first optical device 210. This is a case when the diffraction part DP2 of the second optical device 230 rotates counterclockwise in the curved machining portion (point P3 to point P4) of the workpiece 10.

In contrast, in a case that the diffraction part DP2 of the second optical device 230 rotates clockwise, the diffraction part DP2 of the second optical device 230 may be tilted counterclockwise by the angle θ2-θ1 compared to the diffraction part DP1 of the first optical device 210 in the initial state.

The diffraction part DP2 of the second optical device 230 may start rotating before the cutting of the straight machining portion (point P1 to point P3) of the workpiece 10 is completed.

That is, while the laser beam is passing through the first optical device 210, the diffraction part DP2 of the second optical device 230 may begin to rotate.

For example, when the laser beam passes through point P2 on the workpiece 10, the diffraction part DP2 of the second optical device 230 may begin to rotate.

The diffraction part DP2 of the second optical device 230 starts rotating in advance, so that when cutting the workpiece 10 transitions from the straight machining portion (point P1 to point P3) to the curved machining portion (point P3 to point P4), there may be a moment when the shapes of the diffraction part DP1 of the first optical device 210 and the shape of the diffraction part DP2 of the second optical device 230 coincide.

That is, when the laser beam (i.e., the output light LA2) passes through point P2 on the workpiece 10 (at the process time T2 in FIG. 6), the diffraction part DP2 of the second optical device 230 begins to rotate, and when the laser beam passes through point P3 on the workpiece 10 (at process time T3 in FIG. 6), the diffraction pattern of the diffraction part DP1 of the first optical device 210 and the diffraction pattern of the diffraction part DP2 of the second optical device 230 may match each other.

Accordingly, the cutting process can be transitioned from the straight machining portion to the curved machining portion at a constant speed without reducing the speed at which the scanning unit 250 changes the path of the laser beam (i.e., the output light LA2).

The optical path selection part 300 may change the travel path of the laser beam to the diffracting unit DP2 of the rotating second optical device 230 (S40).

The vibration direction (i.e., polarized direction) of the laser beam passing through the second optical device 230 may rotate according to the rotation of the diffraction part DP2.

The rotation angle of the diffraction part DP2 may correspond to the change angle of the curved machining portion of the workpiece 10.

For example, when the tangent of the starting point P3 and the tangent of the ending point P4 of the curved machining portion of the workpiece 10 form an angle of 90°, the diffraction part DP2 also corresponds to the diffraction part DP1 of the first optical device 210 in the initial state that can be rotated up to 90°.

That is, when the tangent at point P2 and the tangent at point P3 are perpendicular to each other, the diffraction part DP2 of the second optical device 230 can rotate by 90°, and in the laser passing through the second optical device 230, the vibration direction of the beam can also be rotated by 90°.

The time taken by the optical path selection part 300 to adjust the path of the laser beam from the first optical device 210 to the second optical device 230 or from the second optical device 230 to the first optical device 210 can be equal to or shorter than the time taken by the scanning unit 250 to move the propagation direction of the laser beam (i.e., the second light LA2).

When the laser beam (i.e., the input light LA1) travels toward the second optical device 230, the diffraction part DP1 of the first optical device 210 may rotate (S42).

The rotation angle θ4-θ2 of the diffraction part DP1 of the first optical device 210 during the time period T3 to T4 may correspond to the angle between the extension line of the first straight machining portion (point P1 to point P3) and the extension line of the second straight machining portion (point P4 to point P5) of the workpiece 10.

As an example, referring to FIGS. 3 and 6, when the angle between the extension line of the first straight machining portion (point P1 to point P3) and the extension line of the second straight machining portion (point P4 to point P5) of the workpiece 10 is 90°, the diffraction part DP1 of the first optical device 210 may also rotate by 90°.

As the diffraction part DP1 of the first optical device 210 rotates, the first optical device 210 may be ready for cutting the second straight line processing portion (point P4 to point P5).

The laser beam (i.e., the output light LA2) emitted from the second optical device 230 proceeds to the scanning unit 250, and the scanning unit 250 may irradiate the incident laser beam along a preset path.

The laser beam emitted from (i.e., passing through) the second optical device 230 is irradiated by the scanning unit 250 to the curved machining portion (point P3 to point P4) on the workpiece 10 to cut the workpiece 10 into a curve (S50).

Since the changing vibration direction (i.e., polarized direction) of the laser beam emitted from the second optical device 230 corresponds to the tangent of the path for cutting the curved machining portion (point P3 to point P4) of the workpiece 10 into a curved line, the workpiece 10 can be cut smoothly without winding along the curved processing part (point P3 to point P4).

At the point (P4 point in process time T4 of FIG. 6) when the cutting of the curved processing part of the processed material (i.e., workpiece 10) is completed, the optical path selection part 300 can change the optical path so that the laser beam is directed towards the first optical device 210 (S60).

The optical path selection part 300 performs an operation to change the path of the laser beam, and at this time, the operation of the optical path selection part 300 is equal to or faster than the moving speed of the path change member of the scanning unit 250.

Since the diffraction part DP1 of the first optical device 210 is rotated to correspond to the second straight machining portion (point P4 to point P5) of the workpiece 10, cutting of the second straight machining portion (point P4 to point P5) may proceed by changing the travel path of the laser beam.

When the travel path of the laser beam is changed to be directed to the first optical device 210, the diffraction part DP2 of the second optical device 230 can rotate to prepare for cutting another curved machining portion of the workpiece 10.

As detailed above, when the cutting of the straight machining portion is underway, the diffraction part DP2 of the second optical device 230 may be tilted clockwise compared to the diffraction part DP1 of the first optical device 210.

That is, it may be tilted to the right by the angle θ4-θ3 relative to the diffraction part DP1 of the first optical device 210 when cutting a straight machining portion.

This is the case when the diffraction part DP2 rotates counterclockwise. In case that the diffraction part DP2 rotates clockwise, the diffraction part DP2 of the second optical device 230 may be tilted counterclockwise compared to (i.e., with respect to) the diffraction part DP1.

Immediately after the travel path of the laser beam is changed to be directed to the first optical device 210, the diffraction part DP2 of the second optical device 230 gradually reduces its rotation speed to a stop state, and then rotates in the opposite direction again as above, so the diffraction part DP2 of the first optical device 210 may be tilted with respect to the diffraction part DP1 of the diffraction part DP1.

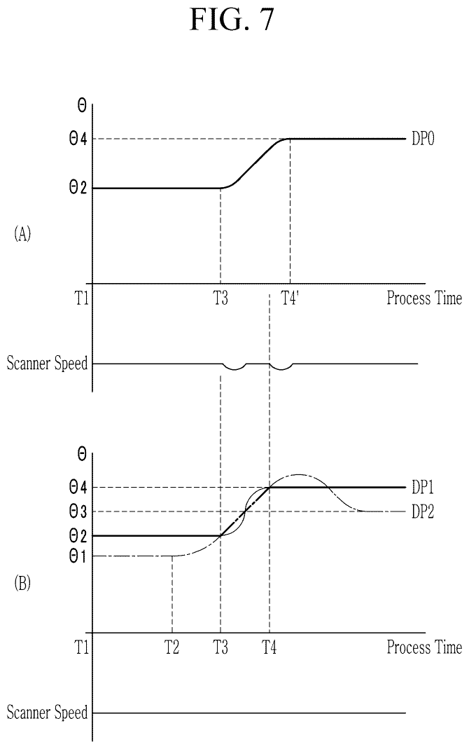

FIG. 7 is a graph comparing laser cutting using a single optical device and laser cutting using a plurality of optical devices according to this embodiment.

(A) of FIG. 7 shows a graph for cutting the workpiece 10 using a laser cutting device in which only one optical device is disposed.

The diffraction part DP0 is in a stationary state during the period from T1 to T3, and during this period, the laser beam passing through the optical device cuts the straight machining portion (point P1 to point P3) of the workpiece 10.

When the time point T3 is reached, the diffraction part (DP0) of the optical device starts rotating to cut the curved machining portion.

At this time, the diffraction part DP0, which was in a stopped state, needs to reduce the speed of the scanning unit (Scanner Speed, the speed of the scanning unit) that changes the movement path of the laser beam, in order to correspond to the delay time until it reaches a certain rotation speed (the speed corresponding to the speed at which the scanning unit changes the movement path of the laser beam).

In addition, while cutting the curved machining portion (point P3 to point P4) of the workpiece 10, the rotation speed of the diffraction part DP0 of the optical device must be lowered.

Therefore, the speed of the scanning unit must be lowered in response to the deceleration of the diffraction part DP0.

(B) of FIG. 7 shows a graph for cutting the workpiece 10 using the laser cutting device of this embodiment.

The laser beam passing through the diffraction part DP1 of the first optical device 210 during which the time period (T1-T3) cuts a straight machining portion of the workpiece 10.

At time T2, the diffraction part DP2 of the second optical device 230 begins to rotate, and when it reaches time T3, the rotation speed of the diffraction part DP2 is set to a constant rotation speed (depending on the speed at which the scanning unit changes the moving path of the laser beam) (the corresponding speed), so it is possible to transition from cutting in a straight machining portion to cutting in a curved machining portion without slowing down the speed of the scanning unit.

Additionally, the diffraction part DP1 of the first optical device 210, which was at an angle of θ2, rotates to θ4 during the time period (T3-T4).

Therefore, when transitioning from cutting the curved machining portion of the workpiece 10 to cutting the straight machining portion at time T4, the speed of the scanning unit can be maintained, so the process time can be shortened by a (T′-T) time.

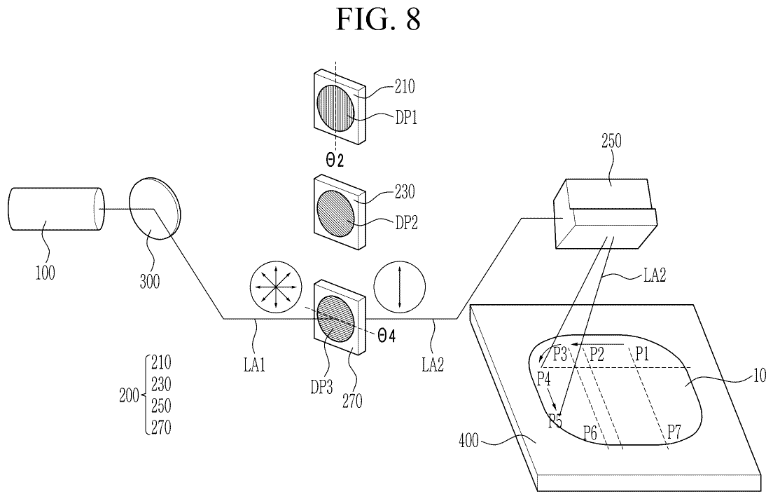

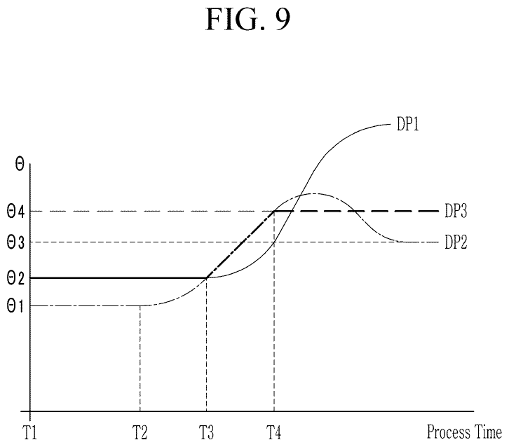

Hereinafter, a laser cutting device according to another embodiment will be described with reference to FIGS. 8 and 9 along with FIGS. 1 to 4.

FIG. 8 is a diagram showing a laser cutting device according to another embodiment, and FIG. 9 is a graph showing a change in a diffraction part over time of a laser cutting device according to another embodiment.

The laser cutting device according to this embodiment is similar to the embodiment described with reference to FIGS. 1 to 4.

Detailed descriptions of the same components are omitted.

Referring to FIG. 8, the laser cutting device according to this embodiment may further include a third optical device 270 in the optical system 200.

The third optical device 270 can convert the input light LA1 into the output light LA2.

The third optical device 270 may be a diffractive optical device.

The third optical device 270 may include a diffraction part DP3 that converts the input light LA1 into the output light LA2.

That is, the input light LA1 whose vibration direction is not specified may be converted into the output light LA2 having a vibration direction (i.e., polarized direction) after passing through the diffraction part DP3 of the third optical device 270.

The diffraction part DP3 of the third optical device 270 may have a diffraction pattern having a specific direction.

The diffraction part DP3 of the third optical device 270 may have the same shape, and only the direction of the diffraction pattern may be different.

The diffraction part DP3 of the third optical device 270 in its initial state before the cutting process begins may have a diffraction pattern in a different direction from that of the diffraction part DP1 of the first optical device 210.

The angle formed by the diffraction pattern of the diffraction part DP1 of the first optical device 210 and the diffraction pattern of the diffraction part DP3 of the third optical device 270 is an extension of the first straight machining portion on the workpiece 10 and it may correspond to the angle formed by the extension line of the second straight machining portion.

That is, referring to FIG. 9, the diffraction pattern of the diffraction part DP3 of the third optical device 270 and the diffraction pattern of the diffraction part DP1 of the first optical device 210 in the initial state before the cutting process starts, the pattern may form an angle θ4-θ2.

For example, when the angle formed by the extension line of the first straight machining portion and the extension line of the second straight machining portion on the workpiece 10 is 90°, the diffraction pattern of the diffraction part DP3 of the third optical device 270 and the first diffraction pattern of the diffraction part DP1 of the first optical device 210 may form an angle of 90°.

Hereinafter, a method of cutting a workpiece using a laser cutting device according to another embodiment will be described with reference to FIGS. 8 and 9.

The laser cutting method according to this embodiment is similar to the laser cutting method described with reference to FIG. 5 and FIG. 6.

Detailed description of the same procedures is omitted.

After cutting the first straight machining portion (point P1 to point P3) of the workpiece 10 is completed, the diffraction part DP1 of the first optical device 210 rotates.

At this time, the diffraction part DP1 of the first optical device 210 may rotate to have a diffraction pattern corresponding to the third straight machining portion (point P6 to point P7) of the workpiece 10.

For example, when the first straight machining portion (point P1 to point P3) and the third straight machining portion (point P6 to point P7) are parallel, the diffraction part DP1 of the first optical device 210 may not rotate.

When cutting of the first curved machining portion (point P3 to point P4) of the workpiece 10 is completed, the optical path selection part 300 may adjust the propagation direction of the laser beam so that it faces the third optical device 270.

The laser beam that has passed through the third optical device 270 can be irradiated along the second straight machining portion (point P4 to point P5) of the workpiece 10 by the scanning unit 250 to cut the workpiece 10.

According to the laser cutting method using the laser cutting device according to this embodiment, the workpiece 10 can be processed without deceleration even when the travel path movement speed of the laser beam by the scanning unit is too fast.

That is, when the diffraction part DP1 of the first optical device 210 is rotated at a small angle such as 90° or less, the first optical device 210 may not be rotated corresponding to the second straight machining portion (point P4 to point P5) before cutting of the curved machining portion is completed due to limitations in acceleration. According to this embodiment, if the rotation of the diffraction part DP1 cannot be completed, the fast speed of the scanning unit can be responded to by passing the laser beam through the third optical device 270.

Although the embodiments of the present invention have been described in detail above, the scope of the present invention is not limited thereto, and various modifications and improvements can be made by those skilled in the art using the basic concepts of the present invention defined in the following claims.

### DESCRIPTION OF SYMBOLS

100: light source part
200: optical system
210: first optical device
230: second optical device
250: scanning unit
270: third optical device
300: optical path selection part
400: stage

What is claimed is:

1. A laser cutting device, comprising:
a light source part configured to emit a laser beam;
a stage where a workpiece is placed;
an optical system including a scanning unit configured to irradiate the laser beam to the stage and change an irradiation direction of the laser beam along a shape set for the workpiece, and optical devices disposed on a path of the laser beam, which is from the light source part to the scanning unit; and
an optical path selection part disposed between the light source part and the optical system and configured to adjust the path of the laser beam so that the laser beam moves to one of the optical devices.

2. The laser cutting device of claim 1, wherein
the optical devices include a first optical device and a second optical device each having a diffraction part configured to convert an incident laser beam into polarized light, and
the diffraction part has a diffraction pattern in which a vibration direction of the polarized light is selected.

3. The laser cutting device of claim 2, wherein
the diffraction pattern of the diffraction part of the first optical device and the diffraction pattern of the diffraction part of the second optical device are different from each other in a stationary state.

4. The laser cutting device of claim 3, wherein
the diffraction pattern of the diffraction part of the second optical device in the stationary state is tilted, compared to the diffraction pattern of the diffraction part of the first optical device, in a direction opposite to a direction in which the diffraction part of the second optical device rotates.

5. The laser cutting device of claim 2, wherein
a rotation time of the diffraction part of the first optical device and a rotation time of the diffraction part of the second optical device do not at least partially overlap.

6. The laser cutting device of claim 2, wherein
the set shape of the workpiece has a straight machining portion and a curved machining portion, and
the optical path selection part adjusts the path of the laser beam to be directed to the first optical device during cutting the straight machining portion, and adjusts the path of the laser beam to be directed to the second optical device during cutting the curved machining portion.

7. The laser cutting device of claim 2, wherein
the diffraction part of the first optical device is in a stationary state when the laser beam is incident on the first optical device, and
the diffraction part of the second optical device is in a rotating state when the laser beam is incident on the second optical device.

8. The laser cutting device of claim 1, wherein
the scanning unit changes the path of the laser beam at a constant speed.

9. The laser cutting device of claim 2, wherein
the optical devices further include a third optical device having a diffraction part configured to convert an incident laser beam into polarized light,
the diffraction part has a diffraction pattern in which a vibration direction of the polarized light is selected, and
the diffraction pattern of the diffraction part of the first optical device, the diffraction pattern of the diffraction part of the second optical device, and the diffraction pattern of the diffraction part of the third optical device are different from each other in a stationary state.

10. The laser cutting device of claim 9, wherein
the set shape of the workpiece has a straight machining portion and a curved machining portion, and
the optical path selection part adjusts the path of the laser beam to be directed to the first optical device or the third optical device during cutting the straight machining portion, and adjusts the path of the laser beam to be directed to the second optical device during cutting the curved machining portion.

11. A laser cutting method, comprising
preparing a workpiece on a stage,
emitting a laser beam from a light source and selectively entering the laser beam into a first optical device or a second optical device, and
cutting the workpiece by a scanning unit to move an irradiation direction of the laser beam, to the stage, outputted from the first optical device or the second optical device along a shape set for the workpiece.

12. The laser cutting method of claim 11, wherein
the selectively entering of the laser beam on the first optical device or the second optical device includes adjusting a path of the laser beam, which is from the light source part to the scanning unit, by an optical path selection part.

13. The laser cutting method of claim 11, wherein
the shape set for the workpiece includes a straight machining portion and a curved machining portion,
the straight machining portion is cut by the laser beam, which passes through the first optical device, and
the curved machining portion is cut by the laser beam, which passes through the second optical device.

14. The laser cutting method of claim 12, wherein
the adjusting of the path of the laser beam by the optical path selection part includes:
adjusting the path of the laser beam to be directed to the first optical device when a diffraction part of the first optical device is in a stationary state, and adjusting the path of the laser beam to be directed to the second optical device when a diffraction part of the second optical device is in a rotating state.

15. The laser cutting method of claim 13, wherein
a vibration direction of the laser beam passing through the first optical device is parallel to the straight machining portion of the workpiece.

16. The laser cutting method of claim 13, wherein
the vibration direction of the laser beam passing through the second optical device rotates, and
the vibration direction of the laser beam passing through the second optical device corresponds to a tangent of the curved machining portion of the workpiece.

17. The laser cutting method of claim 14, wherein
the diffraction part of the second optical device starts rotating when the laser beam enters into the first optical device.

18. The laser cutting method of claim 12, wherein
time required to adjust the path of the laser beam by the optical path selection part is equal to or shorter than time required for the scanning unit to change the irradiation direction of the laser beam.

19. The laser cutting method of claim 14, wherein
the diffraction part of the first optical device starts rotating when the laser beam enters into the second optical device.

20. The laser cutting method of claim 13, wherein
the straight machining portion includes a first straight machining portion and a second straight machining portion,
the first straight machining portion is cut by the laser beam passing through the first optical device,
the second straight machining portion is cut by the laser beam passing through a third optical device, and
an extension line of the first straight machining portion and an extension line of the second straight machining portion intersect each other.
